(19) United States
(12) Patent Application Publication
(10) Pub. No.: US 2021/0104563 A1
(43) Pub. Date: Apr. 8, 2021

(54) ULTRA-THIN PACKAGE STRUCTURE FOR INTEGRATED CIRCUIT HAVING SENSING FUNCTION AND METHOD FORMING THE SAME

(71) Applicant: SunASIC Technologies, Inc., Taipei City (TW)

(72) Inventors: Chi-Chou LIN, New Taipei City (TW); Zheng Ping HE, Taipei (TW)

(21) Appl. No.: 16/590,463

(22) Filed: Oct. 2, 2019

(51) Int. Cl. H01L 27/146; H01L 23/31; H01L 23/66; H01L 21/48; H01L 23/29; H01L 25/16; H01L 23/13

(52) U.S. Cl. CPC H01L 27/14618; H01L 2223/6677; H01L 23/3135; H01L 27/14636; H01L 27/1462; H01L 27/14643; H01L 27/14678; H01L 23/66; H01L 27/14685; H01L 21/4857; H01L 27/1469; H01L 23/3171; H01L 23/293; H01L 23/3121; H01L 25/165; H01L 23/13; H01L 2223/6616; H01L 27/14634

(57) ABSTRACT

An ultra-thin package structure for an integrated circuit having sensing functions is disclosed. It includes: a first substrate layer, having a first top side and a first bottom side, wherein a plurality of conductive traces are formed on the first top side and the first bottom side; an integrated circuit, having at least one gold-plated die pad on the top side thereof, wherein the at least one gold-plated die pad is connected to the corresponding conductive trace on the first bottom side of the first substrate layer by SMT; a second substrate layer, having a second top side and a second bottom side, wherein a plurality of conductive traces are formed on the second bottom side, and some portions of the conductive traces are covered by solder mask while other portions are exposed externally; and a filling material layer, formed between the first and the second substrate layer with the integrated circuit therebetween.

### FIELD OF THE INVENTION

The present invention relates to an ultra-thin package structure and a method to form the ultra-thin package structure. More particularly, the present invention relates to an ultra-thin package structure for an integrated circuit having sensing functions and a method to form the ultra-thin package structure.

### BACKGROUND OF THE INVENTION

It is a trend to make electronic products small in size and compact in thickness. There are many issues, such as heat dissipation, which need to be settled during the design process. One of these issues is how to consolidate necessary components into an integrated circuit (IC) or a printed circuit board (PCB). An electronic component can be embedded in a printed circuit board during the printed circuit board manufacturing processes. The technique started from buried resistor technology from Ohmega Technologies, Inc. Although it was only passive components can be used in the beginning, it becomes well accepted to the industrial nowadays that active components can be applied by various modifications and invention.

Among all integrated circuits, there are several kinds which have specific functions and need to work interactively with external environment, such as charge-coupled devices (CCD) and CMOS image sensors. A camera sensor and a mouse sensor are typical products for the CCD and CMOS image sensor, respectively. A capacitive fingerprint reader is another example. The fingerprint reader sensor needs to detect the change of capacitance, and the mouse sensor needs to receive light change across a surface. Even those integrated circuits are embedded into a PCB, it is required a proper arrangement and configuration for the integrated circuits to expose to the external environment. Meanwhile, a good design for the integrated circuits to work is important as well.

Reviewing the prior arts, there are several inventions that have focused on some of the requirements mentioned above. U.S. Pat. Nos. 8,083,954, 8,302,299, and US Patent Application No. 20130092420 gave great solutions for embedding electronic device into PCB. However, they are not suitable for active electronic devices for sensing, such as a CCD/CMOS image sensor, or capacitive fingerprint sensor that is exposed to or close to the environment.

U.S. Pat. No. 7,090,139 discloses an IC card and method of manufacturing it. According to '139, the electric devices are connected to the wirings through anisotropic conductive films. This method significantly decreases the total thickness of the package to the thickness requirement of an IC card. However, while the device is a sensor that is exposed to the environment or is placed close to the external environment, providing electro-static discharge (ESD) protection to the sensor is an important issue. The limited current carrying capability of the anisotropic conductive film will be a problem for the protection circuit to dissipate the ESD current and cause damage to the sensor.

In order to reduce the thickness of the package with an electronic device (chip), the inventor of the present invention also disclosed a method in U.S. Pat. No. 9,295,198. According to '198, a chip embedded in a 3-layer PCB structure without bond wires can be manufactured. However, the total thickness of the package may be further reduced to fit the requirement of a card, a card-like device, or a wearable device.

For this, another improved method of our previous invention to package the devices described above is desired.

### SUMMARY OF THE INVENTION

This paragraph extracts and compiles some features of the present invention; other features will be disclosed in the follow-up paragraphs. It is intended to cover various modifications and similar arrangements included within the spirit and scope of the appended claims.

In order to fulfill the requirements and settle the problems mentioned above, an ultra-thin package structure for an integrated circuit having sensing functions is provided. The ultra-thin package structure comprises: a first substrate layer, having a first top side and a first bottom side, wherein a plurality of conductive traces are formed on the first top side and the first bottom side; an integrated circuit, having at least one gold-plated die pad on the top side thereof, wherein the at least one gold-plated die pad is connected to the corresponding conductive trace on the first bottom side of the first substrate layer by Surface-Mount Technology (SMT); a second substrate layer, having a second top side and a second bottom side, wherein a plurality of conductive traces are formed on the second bottom side, and some portions of the conductive traces are covered by solder mask while other portions are exposed externally; and a filling material layer, formed between the first substrate layer and the second substrate layer and around the integrated circuit, adhering the substrate layers and fixing the integrated circuit therebetween. At least one plated via hole is formed through the second substrate layer, the filling material layer and the first substrate layer, connecting the conductive traces formed on the second substrate layer and the first substrate layer.

Preferably, the integrated circuit may be covered by a protective coating layer except that the at least one gold-plated die pad is not covered by the protective coating layer. The protective coating layer may contain insulating and passivation organic materials. The insulating and passivation organic material may be Polyimide (PI). A number of active components and passive components may be fixed in the filling material layer, and each component is connected to the corresponding conductive trace on the first bottom side of the first substrate layer by SMT. The filling material layer may be made of thermosetting material. The thermosetting material may be resin or Pre-impregnated Bonding Sheet (Pre-Preg).

According to the present invention, the ultra-thin package structure for an integrated circuit having sensing functions further comprises solder mask formed on a portion of the first top side, wherein some portions of the conductive traces on the first top side are covered by solder mask. It may also comprise a metal bezel or a metal frame, connected to some conductive traces on the first top side of the first substrate layer, for enhancing the structural strength of the ultra-thin package structure and/or for functioning as a signal transmitting interface. The metal bezel does not cover a top projected area of the integrated circuit. The metal bezel connected to some conductive traces on the first top side of the first substrate layer may be achieved by soldering or a conductive paste.

Preferably, the integrated circuit may be an image sensor. A portion of the first substrate layer may be removed to form an opening to expose a sensing portion of the image sensor. A dam structure may be formed on the first bottom side of the first substrate layer and around the opening to prevent filling materials of the filling material layer from overflowing from the opening. The image sensor may be a fingerprint sensor or a Complementary Metal-Oxide-Semiconductor (CMOS) sensor. One conductive trace on the second substrate layer or the first substrate layer may further form a trace antenna. Materials of the second substrate layer and the first substrate layer may be high glass-transition temperature (Tg) material. The first substrate layer and second substrate layers may be made of a glass-reinforced epoxy laminate material of FR4 or FR5, polyester or polyethylene terephthalate (PET). The first substrate layer has a thickness less than or equal to 75 μm, and the total thickness of the ultra-thin package structure is less than 550 μm.

A method to form the ultra-thin package structure for an integrated circuit having sensing functions is also provided. The method comprises the steps of: a. providing a first substrate layer which is a woven glass epoxy base material clad with copper foil on a bottom side thereof; b. fixing a first copper foil onto a carrier; c. fixing a top side of the first substrate layer above the first copper foil onto the carrier; d. mounting an integrated circuit and active and passive components to the first substrate layer by SMT; e. attaching a second substrate layer to the first substrate layer and the integrated circuit; f. attaching a second copper foil onto the second substrate layer; g. laminating the ultra-thin package structure from steps above in a vacuum or a low-pressure environment; h. etching the first and second copper foils to form specific traces, and coating a top side of the first substrate layer and the bottom side of the second substrate layer with the solder mask; and i. removing unnecessary portions of the solder masks.

The present invention also provides another method to form the ultra-thin package structure for an integrated circuit having sensing functions. It comprises the steps of: a. providing a first substrate layer; b. removing a portion of the first substrate layer to form an opening; c. forming a dam structure on a first bottom side of the first substrate layer and around the opening; d. fixing the first substrate layer onto a carrier; e. mounting an integrated circuit and active and passive components to the first substrate layer by SMT with a sensing portion of the integrated circuit exposed externally through the opening; f. applying filling material around the integrated circuit and the active and passive components; g. attaching the second substrate layer over the filling material; h. laminating the ultra-thin package structure from above steps in a vacuum or a low-pressure environment to finish packaging processes; and i. coating a first top side of the first substrate layer and a bottom side of the second substrate layer with the solder masks, and then removing unnecessary portions of the solder masks.

### BRIEF DESCRIPTION OF THE DRAWINGS

FIG. 1 is a schematic diagram (cross-sectional view) showing an ultra-thin package structure for an integrated circuit having sensing functions having sensing functions according to the present invention.

FIG. 2 shows a top view of an example of a metal bezel.

FIG. 3 shows two different top views of the ultra-thin package structure with a trace antenna formed on a first substrate layer.

FIG. 4 is a flow chart of a method to form the ultra-thin package structure for the integrated circuit having sensing functions.

FIG. 5 is another schematic diagram (cross-sectional view) showing another ultra-thin package structure for an integrated circuit having sensing functions according to the present invention.

FIG. 6 is another flow chart of another method to form the ultra-thin package structure for the integrated circuit having sensing functions.

FIG. 7 is another schematic diagram (cross-sectional view) showing another ultra-thin package structure for an integrated circuit having sensing functions according to the present invention.

FIG. 8 is another schematic diagram (cross-sectional view) showing another ultra-thin package structure for an integrated circuit having sensing functions according to the present invention.

### DETAILED DESCRIPTION OF THE PREFERRED EMBODIMENTS

The present invention will now be described more specifically with reference to the following embodiments.

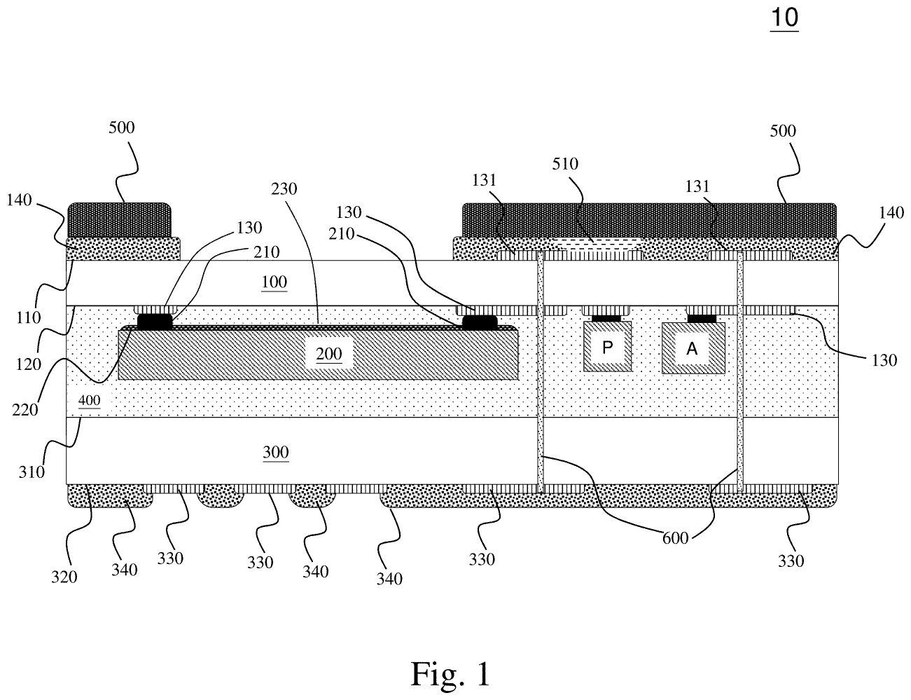

A cross-sectional view of an ultra-thin package structure 10 for an integrated circuit having sensing functions according to the present invention is showing in FIG. 1. The ultra-thin package structure 10 has a first substrate layer 100, an integrated circuit 200, a second substrate layer 300, a filling material layer 400 and a metal bezel 500. It should be noted that the ratio of portrait to landscape may not be the same as the ultra-thin package structure 10 is implemented. An enlarged portrait is able to show more details of the ultra-thin package structure 10. A thorough description of each element is given below.

The first substrate layer 100 has a first top side 110 and a first bottom side 120. A number of conductive traces 130 are formed on the first bottom side 120, and A number of conductive traces 131 are formed on the first top side 110. The first substrate layer 100 may be made of a glass-reinforced epoxy laminate material of FR4 or FR5, Cyanate Ester-based resin laminate material, Bismaleimide Triazine-based laminate material, polyester or polyethylene terephthalate (PET). In practice, the first substrate layer 100 may also be a high glass-transition temperature (Tg) material.

The integrated circuit 200 has at least one gold-plated die pad 210 on its top side and is fixed by the filling material layer 400. The gold-plated die pad 210 may be plated with gold or gold alloy to increase the bondability (or solder wettability) thereof. In the present embodiment, only two gold-plated die pads 210 are drawn for illustration. The integrated circuit 200 has features that it needs to work with external objects or sense change of external energy and protected by a thin protector. For example, the integrated circuit 200 may be an image sensor. More particularly, the image sensor may be a fingerprint sensor or a (Complementary Metal-Oxide-Semiconductor) CMOS sensor. The integrated circuit 200 may be manufactured in different forms, i.e., a die or a packaged chip. The integrated circuit 200 is covered by a protective coating layer 220 except that the two gold-plated die pads 210 are not covered by the protective coating layer 220. The protective coating layer 220 may contain insulating and passivation organic materials, such as Polyimide (PI). The two gold-plated die pads 210 are connected to the corresponding conductive trace 130 on the first bottom side 120 of the first substrate layer 100 by Surface-Mount Technology (SMT).

The second substrate layer 300 having a second top side 310 and a second bottom side 320. As the first substrate layer 100, there are a number of conductive traces 330 formed on the second bottom side 320. The only difference between the second substrate layer 300 and the first substrate layer 100 is there may not be conductive traces on the second top side 310. As shown in FIG. 1, some portions of the conductive traces 330 are covered by solder mask 340 while other portions are exposed. The second substrate layer 300 may be made of a glass-reinforced epoxy laminate material of FR4 or FR5, Cyanate Ester-based resin laminate material, Bismaleimide Triazine-based laminate material, polyester or polyethylene terephthalate (PET). Preferably, the second substrate layer 300 may also be a high glass-transition temperature (Tg) material.

In order to operate the integrated circuit 200 properly, there might be active components and/or passive components (an active component A and a passive component P are used for illustration in FIG. 1) fixed in the filling material layer 400. Each component is connected to the corresponding conductive trace 130 on the first bottom side 120 of the first substrate layer 100 by SMT. It can be easily seen in FIG. 1 that a solder mask 140 formed on a portion of the first top side 110. Some portions of the first top side 110 of the first substrate layer 100 are covered by the solder mask 140. The solder mask 140 can protect the conductive trace 130 from erosion.

The filling material layer 400 formed between the first substrate layer 100 and the second substrate layer 300 and around the integrated circuit 200. The filling material layer 400 adheres the two substrate layers and fixing the integrated circuit 200 between them. The filling material layer 400 is made of thermosetting material. Preferably, the thermosetting material can be resin or Pre-impregnated Bonding Sheet (Pre-Preg). It should be noticed that the filling material layer 400 is formed between the first substrate layer 100 and the second substrate layer 300 under a negative pressure environment so that the filling material can flow to occupy the places therebetween. The negative pressure environment helps to eliminate the void (air holes) between the first substrate layer 100 and the second substrate layer 300 during a laminating process to form the ultra-thin package structure 10. In another embodiment, while the filling material layer 400 is Pre-Preg sheet, a portion of the Pre-Preg may be removed before been attached to the first substrate layer 100. The removed portion is corresponding to the size and location of the integrated circuit 200, the active components and/or passive components. Therefore, the finished package may be thinner, and there may be less void around the integrated circuit 200, the active components and passive components.

At least one plated via hole 600 (two plated via holes 600 are plotted in FIG. 1 for illustration) is formed through the second substrate layer 300, the filling material layer 400 and the first substrate layer 100. The plated via holes 600 connect the conductive traces formed on the second substrate layer 300 and the first substrate layer 100 for internal conduction of electrical signals.

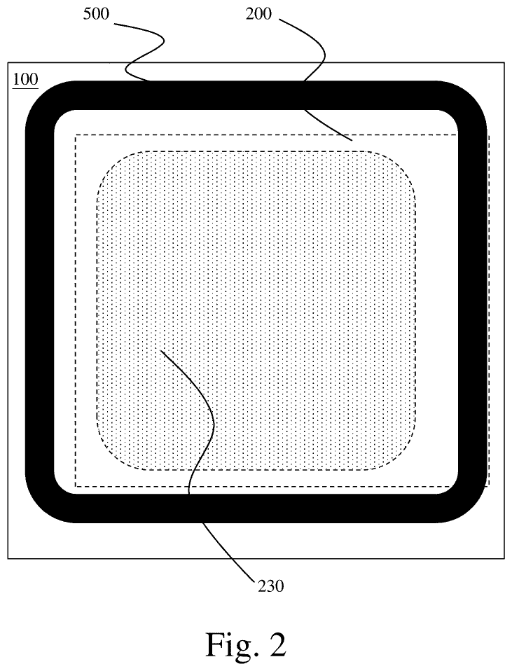

The metal bezel 500 (or a metal frame) is connected to some conductive traces 130 on the first top side 110 of the first substrate layer 100. The metal bezel 500 is able to enhance the structural strength of the ultra-thin package structure 10 and/or function as a signal transmitting interface (e.g., transferring a signal from/to the integrated circuit 200). In some example, the metal bezel 500 can further form an antenna as a signal transmission media. In one example, while the integrated circuit 200 is a fingerprint sensor, the metal bezel 500 does not cover the top projected area of a sensing portion of the integrated circuit 200. For a better understanding, please see FIG. 2. It shows a top view of an example of the metal bezel 500. The metal bezel 500 is above the integrated circuit 200 (marked by a dashed rectangular frame) with some portions cross (covering) a piece of the integrated circuit 200. Take the integrated circuit 200 as a capacitive fingerprint sensor. A hollow part of the metal bezel 500 is left for a sensing portion 230 of the integrated circuit 200 to fetch the image of a finger by measuring electrical potential or current values at every pixel of the sensing portion 230 when the finger is placed on it. Under this situation, the metal bezel 500 can be used to provide electrical signals (potential changes) to the finger. The area (hollow part of the metal bezel 500) on the first top side 110 above the integrated circuit 200 may not be covered by solder mask in order to increase the sensitivity. The metal bezel 500 is connected to some conductive traces 130 on the first top side 110 of the first substrate layer 100. It is achieved by soldering or a conductive paste 510.

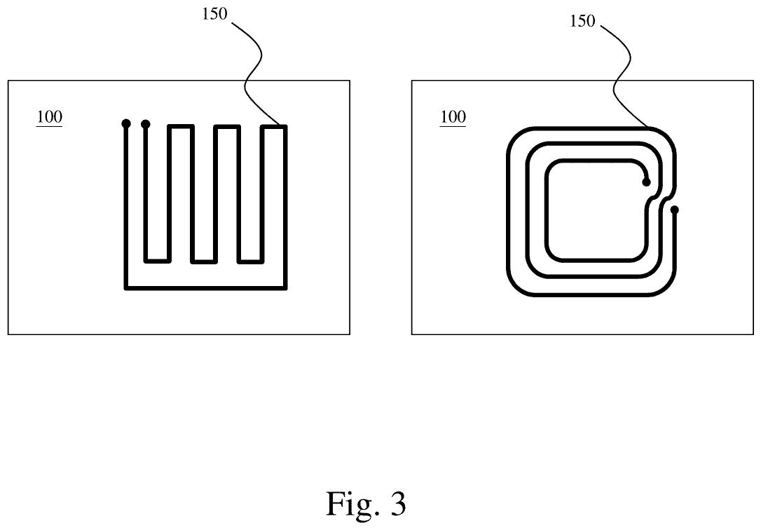

In another embodiment, the metal bezel 500 is absent and replaced by one trace on the first top side 110 to function as the signal transmission media. In still another embodiment, one conductive trace 330 on the second substrate layer 300 or one conductive trace 130 on the first substrate layer 100 can further form a trace antenna. For a better understanding, please see FIG. 3. It shows two different top views of the ultra-thin package structure 10 with a trace antenna 150 formed on the first substrate layer 100. The trace antenna 150 can help the integrated circuit 200 send and receive radio wave to communicate with other devices.

It should be emphasized that the package structure is “ultra-thin” for the integrated circuit 200 since the components formed for the package structure is very thin. According to the present invention, the first substrate layer 100 has a thickness less than or equal to 75 μm. Meanwhile, the total thickness of the ultra-thin package structure is less than 550 μm.

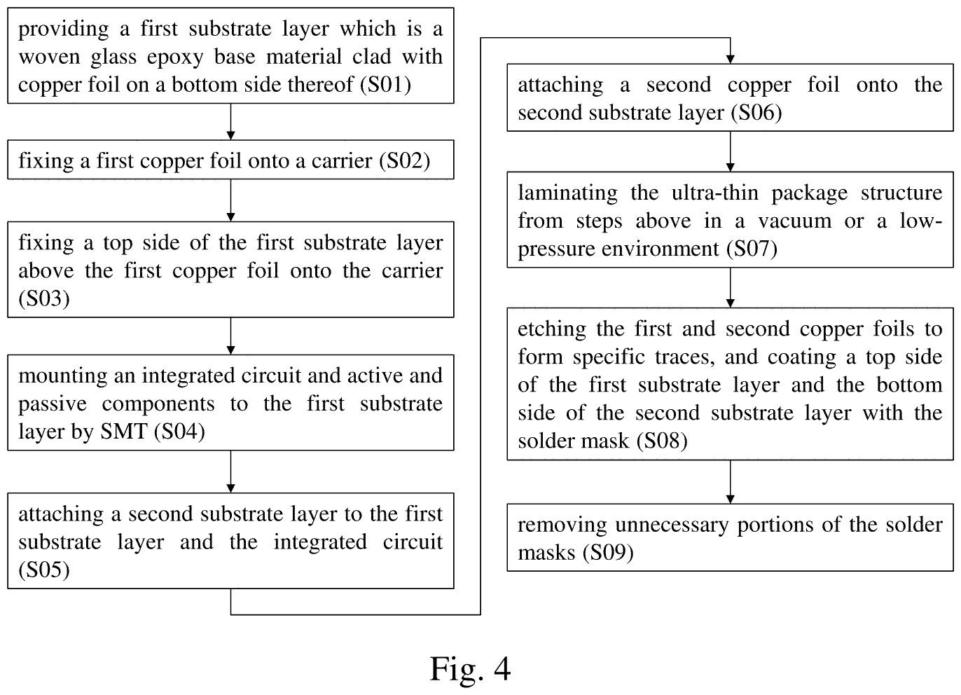

In this embodiment, it provides a method to form the ultra-thin package structure 10 for the integrated circuit 200. A flow chart is shown in FIG. 4. Please notice that the “top” and “bottom” described here is used to describe the finished package structure, which may be different from the manufacturing process. A first step is providing the first substrate layer 100, which is a woven glass epoxy base material clad with copper foil on a bottom side thereof (S01). The copper on the bottom side has already etched to form conductive traces. Then, fix a first copper foil, which will form conductive traces on the first top side later, onto a carrier (not shown) (S02). Then, fix a top side of the first substrate layer 100 above the first copper foil onto the carrier (S03). The carrier is used to fix the first substrate layer 100 to prevent deformation of the first substrate layer 100 while coupling to other components thereon. A fourth step is mounting the integrated circuit 200 and the active and passive components to the bottom side of the first substrate layer 100 by SMT (S04). After the fourth step, attaching the second substrate layer 300 to the first substrate layer 100 and the integrated circuit 200 (S05). Here, the filling material is epoxy resin pre-impregnated in the second substrate layer 300, and is activated and “melts” to fill the space around the integrated circuit 200 during the lamination process from pressure and heat. A sixth step is attaching a second copper foil, which will form the conductive traces 330 on the second bottom side 320 later, onto the second substrate layer 300 (S06). A seventh step is laminating the ultra-thin package structure 10 from the previous steps in a vacuum or a low-pressure (air pressure) environment (S07). An eighth step is etching the first and second copper foils to form specific traces, and coating the first top side 110 and the second bottom side 320 with the solder masks (S08). Finally, removing those unnecessary portions of the solder masks (S09). There may be additional steps to attach the metal bezel to the first top side 110 of the first substrate layer 100.

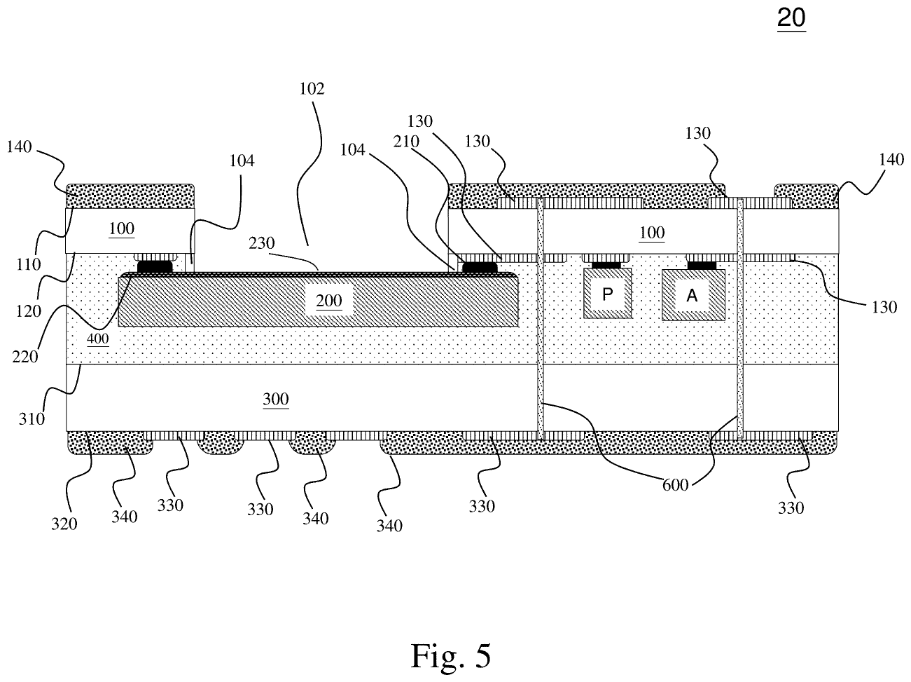

For a requirement that the integrated circuit 200 needs to expose externally for some specific function, e.g., sensing light beams for a CMOS sensor, the present invention can be applied, too. For a better understanding, please refer to FIG. 5 along with a description for another embodiment below. FIG. 5 is another schematic diagram (cross-sectional view) showing another ultra-thin package structure 20 for an integrated circuit having sensing functions according to the present invention.

In order to simplify the description of the ultra-thin package structure 20, some components are used the same as those in FIG. 1 of the previous embodiment. The same symbol has the same functions. In this embodiment, a portion of the first substrate layer 100 is removed to form an opening 102 to expose a sensing portion of the integrated circuit 200 (image sensor). In addition, a dam structure 104 is formed on the first bottom side 120 of the first substrate layer 100 and around the opening 102. The sensing portion 230 of the integrated circuit 200 is surrounded by the dam structure 104 to prevent the filling material from overflowing from the opening 102 during the manufacturing process. The dam structure 104 has a height low enough to allow the integrated circuit 200 been soldered properly during the SMT process. Because the CMOS sensor does not require a signal transmit interface, the metal bezel 500 is not included in the package. There may be an additional protective layer (not shown) formed on the top surface of the CMOS sensor and inside the opening 102. The additional protective layer may be a transparent coated film, or a transparent glass attached thereon.

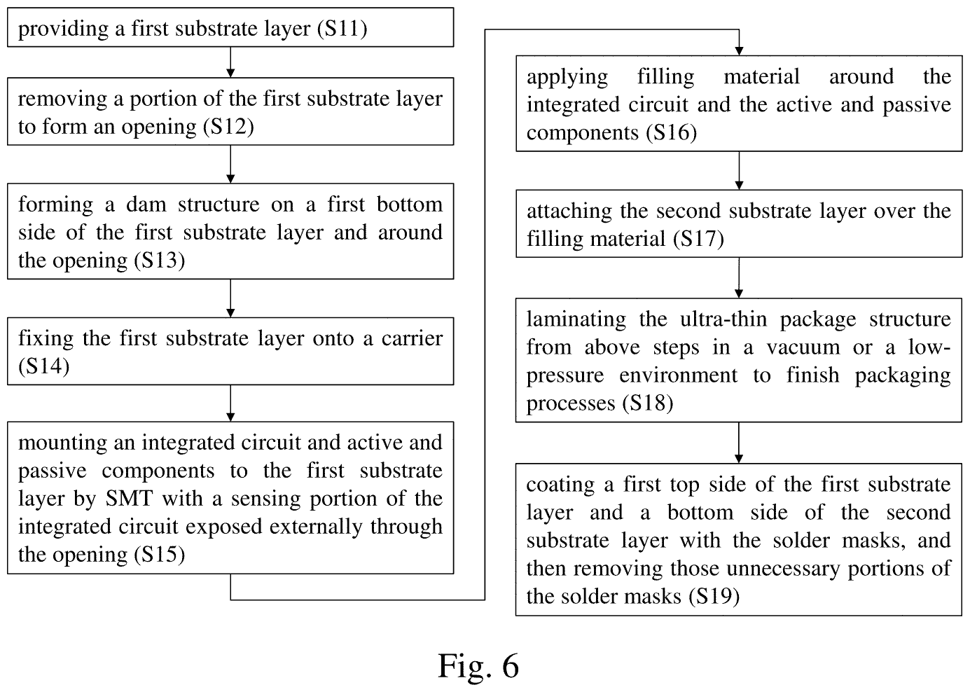

In this embodiment, it also provides a method to form the ultra-thin package structure 20 for the integrated circuit 200. A flow chart is shown in FIG. 6. A first step is providing the first substrate layer 100 (S11). Different from the previous embodiment, the first substrate layer 100 is an FR4 board clad with copper foils on both top and bottom sides. The second step is removing a portion of the first substrate layer 100 to form the opening 102, and etching the copper foils to form conductive traces on both sides thereof (S12). Then, form the dam structure 104 on the first bottom side 120 of the first substrate layer 100 and around the opening 102 (S13). After step S13, fix the first substrate layer 100 onto a carrier (S14). Functions of the carrier are the same as the one in the previous embodiment, and may further have rectangular bulges to prevent the shape of the opening from deformation during later processes. A fifth step is mounting the integrated circuit 200 and the active and passive components to the first substrate layer 100 by SMT with a sensing portion of the integrated circuit 200 exposed through the opening 102 (S15). Then, apply the filling material around the integrated circuit 200 and active and passive components (S16) and attach the second substrate layer 300 over the filling material (S17). The second substrate layer 300 is an FR4 board clad with copper foil on its bottom side, where the copper foil has been etched to form conductive traces. The filling material may be epoxy resin or Pre-Preg. When a Pre-Preg is used as the filling material, a portion of the Pre-Preg corresponding to the integrated circuit 200 and/or the auxiliary components may be removed to fit in the space between the first and second substrate layer. The thickness of the Pre-Preg may be much thinner than an ordinary one to maintain a low profile. In the next step, laminate the ultra-thin package structure 20 from the previous steps in a vacuum or a low-pressure environment to finish the packaging processes (S18). Finally, coating the first top side 110 and the second bottom side 320 with the solder masks, and then removing those unnecessary portions of the solder masks (S19). The steps S13 and S14 may exchange, which will not affect the result.

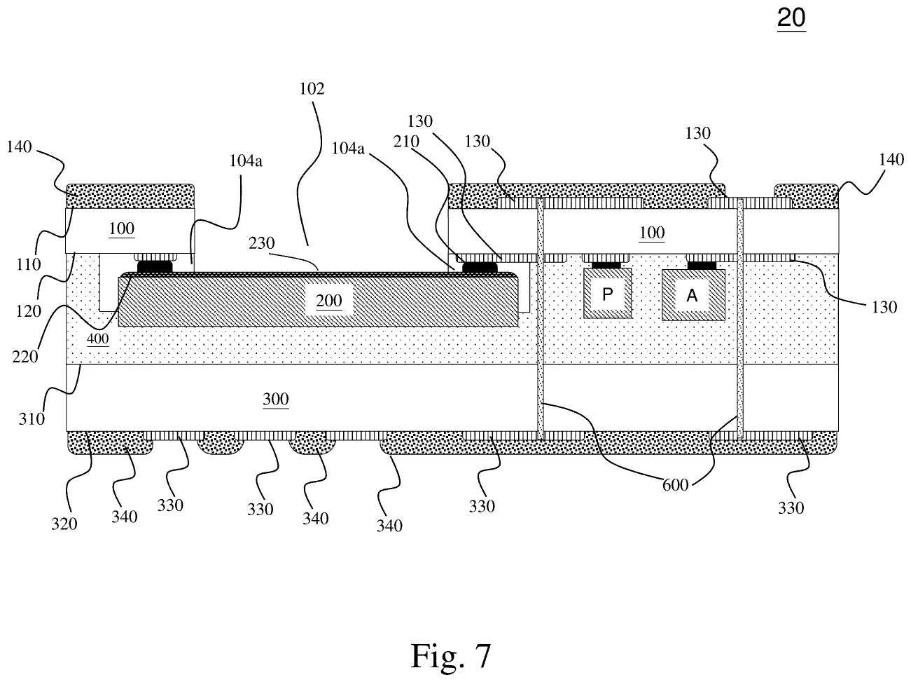

In another embodiment, the dam structure 104 may be replaced by adhesives, which is precisely controlled using a fluid dispenser. Please refer to FIG. 7. All components in FIG. 7 except the adhesives 104a are the same as those in FIG. 5. The adhesives 104a are applied after the SMT step, where all gold-plated die pads 210 and a portion of the conductive trace 130 connected with the gold-plated die pads 210 are sealed by the adhesives. The space between the opening 102 and the integrated circuit 200 are all filled with the adhesives 104a to prevent the filling material from overflowing from the opening 102 during the laminating process.

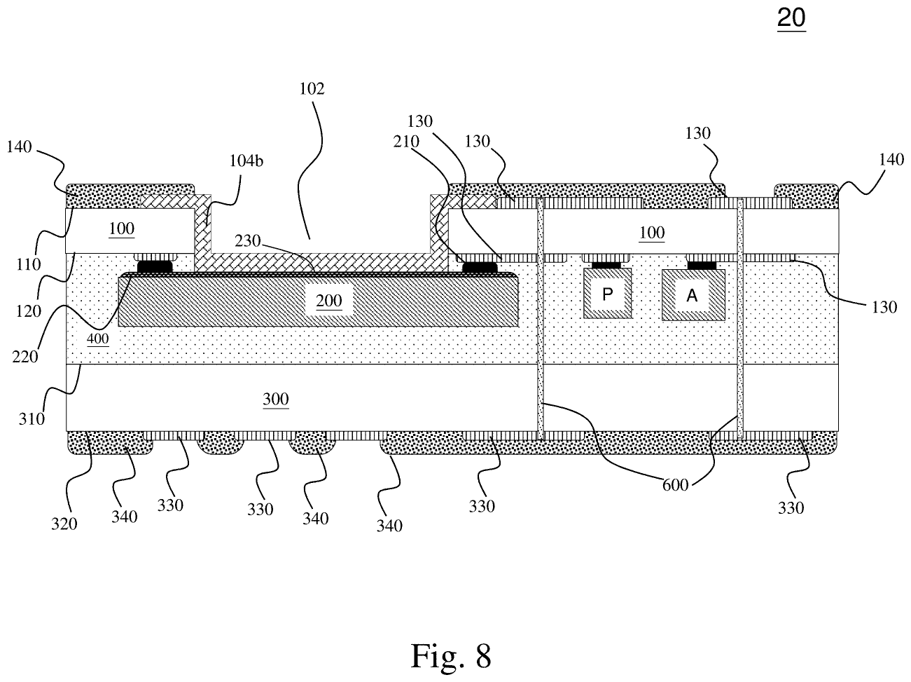

In still another embodiment, the dam structure 104 may be replaced by a thin film 104b formed at the opening 102. Please refer to FIG. 8. All components in FIG. 8 except the thin film 104b are the same as those in FIG. 5. The thin film 104b is applied after the SMT step and is used to prevent the filling material from overflowing from the opening 102 during the laminating process. In one example, the thin film 104b may be formed by attaching a pre-cut film, and then the pre-cut film is pressed down to adhere to the top surface of the integrated circuit 200. In another example, the thin film 104b may be formed by spraying coating and curing. In another example, the thin film 104b may cover the opening and most portion of the first top side 110, and only expose the parts that need to be exposed, such as contacts used to electrically connected to an external device. The solder mask 140 may not be necessary in this example.

While the invention has been described in terms of what is presently considered to be the most practical and preferred embodiments, it is to be understood that the invention needs not to be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. An ultra-thin package structure for an integrated circuit having sensing functions, comprising:
a first substrate layer, having a first top side and a first bottom side, wherein a plurality of conductive traces are formed on the first top side and the first bottom side;
an integrated circuit, having at least one gold-plated die pad on the top side thereof, wherein the at least one gold-plated die pad is connected to the corresponding conductive trace on the first bottom side of the first substrate layer by Surface-Mount Technology (SMT);
a second substrate layer, having a second top side and a second bottom side, wherein a plurality of conductive traces are formed on the second bottom side, and some portions of the conductive traces are covered by solder mask while other portions are exposed externally; and
a filling material layer, formed between the first substrate layer and the second substrate layer and around the integrated circuit, adhering the substrate layers and fixing the integrated circuit therebetween;
wherein at least one plated via hole is formed through the second substrate layer, the filling material layer and the first substrate layer, connecting the conductive traces formed on the second substrate layer and the first substrate layer.

2. The ultra-thin package structure for an integrated circuit having sensing functions according to claim 1, wherein the integrated circuit is covered by a protective coating layer except that the at least one gold-plated die pad is not covered by the protective coating layer.

3. The ultra-thin package structure for an integrated circuit having sensing functions according to claim 2, wherein the protective coating layer contains insulating and passivation organic materials.

4. The ultra-thin package structure for an integrated circuit having sensing functions according to claim 3, wherein the insulating and passivation organic material is Polyimide (PI).

5. The ultra-thin package structure for an integrated circuit having sensing functions according to claim 4, wherein a plurality of active components and passive components are fixed in the filling material layer, and each component is connected to the corresponding conductive trace on the first bottom side of the first substrate layer by SMT.

6. The ultra-thin package structure for an integrated circuit having sensing functions according to claim 1, wherein the filling material layer is made of thermosetting material.

7. The ultra-thin package structure for an integrated circuit having sensing functions according to claim 6, wherein the thermosetting material is resin or Pre-impregnated Bonding Sheet (Pre-Preg).

8. The ultra-thin package structure for an integrated circuit having sensing functions according to claim 1, further comprising solder mask formed on a portion of the first top side, wherein some portions of the conductive traces on the first top side are covered by solder mask.

9. The ultra-thin package structure for an integrated circuit having sensing functions according to claim 1, further comprising a metal bezel or a metal frame, connected to some conductive traces on the first top side of the first substrate layer, for enhancing the structural strength of the ultra-thin package structure and/or for functioning as a signal transmitting interface.

10. The ultra-thin package structure for an integrated circuit having sensing functions according to claim 9, wherein the metal bezel does not cover a top projected area of the integrated circuit.

11. The ultra-thin package structure for an integrated circuit having sensing functions according to claim 9, wherein the metal bezel connected to some conductive traces on the first top side of the first substrate layer is achieved by soldering or a conductive paste.

12. The ultra-thin package structure for an integrated circuit having sensing functions according to claim 1, wherein the integrated circuit is an image sensor.

13. The ultra-thin package structure for an integrated circuit having sensing functions according to claim 12, wherein a portion of the first substrate layer is removed to form an opening to expose a sensing portion of the image sensor.

14. The ultra-thin package structure for an integrated circuit having sensing functions according to claim 13, wherein a dam structure is formed on the first bottom side of the first substrate layer and around the opening to prevent filling materials of the filling material layer from overflowing from the opening.

15. The ultra-thin package structure for an integrated circuit having sensing functions according to claim 12, wherein the image sensor is a fingerprint sensor or a Complementary Metal-Oxide-Semiconductor (CMOS) sensor.

16. The ultra-thin package structure for an integrated circuit having sensing functions according to claim 1, wherein one conductive trace on the second substrate layer or the first substrate layer further forms a trace antenna.

17. The ultra-thin package structure for an integrated circuit having sensing functions according to claim 1, wherein materials of the second substrate layer and the first substrate layer are high glass-transition temperature (Tg) material.

18. The ultra-thin package structure for an integrated circuit having sensing functions according to claim 1, wherein the first substrate layer and second substrate layer are made of a glass-reinforced epoxy laminate material of FR4 or FR5, polyester or polyethylene terephthalate (PET).

19. The ultra-thin package structure for an integrated circuit having sensing functions according to claim 1, wherein the first substrate layer has a thickness less than or equal to 75 um.

20. The ultra-thin package structure for an integrated circuit having sensing functions according to claim 1, wherein the total thickness of the ultra-thin package structure is less than 550 μm.

21. A method to form the ultra-thin package structure for an integrated circuit having sensing functions according to claim 5, comprising the steps of:
a. providing a first substrate layer which is a woven glass epoxy base material clad with copper foil on a bottom side thereof;
b. fixing a first copper foil onto a carrier;
c. fixing a top side of the first substrate layer above the first copper foil onto the carrier;
d. mounting an integrated circuit and active and passive components to the first substrate layer by SMT;
e. attaching a second substrate layer to the first substrate layer and the integrated circuit;
f. attaching a second copper foil onto the second substrate layer;
g. laminating the ultra-thin package structure from steps above in a vacuum or a low-pressure environment;
h. etching the first and second copper foils to form specific traces, and coating a top side of the first substrate layer and the bottom side of the second substrate layer with the solder mask; and
i. removing unnecessary portions of the solder masks.

22. A method to form the ultra-thin package structure for an integrated circuit having sensing functions according to claim 4, comprising the steps of:
a. providing a first substrate layer;
b. removing a portion of the first substrate layer to form an opening;
c. forming a dam structure on a first bottom side of the first substrate layer and around the opening;
d. fixing the first substrate layer onto a carrier;
e. mounting an integrated circuit and active and passive components to the first substrate layer by SMT with a sensing portion of the integrated circuit exposed externally through the opening;
f. applying filling material around the integrated circuit and the active and passive components;
g. attaching the second substrate layer over the filling material;
h. laminating the ultra-thin package structure from above steps in a vacuum or a low-pressure environment to finish packaging processes; and
i. coating a first top side of the first substrate layer and a bottom side of the second substrate layer with the solder masks, and then removing unnecessary portions of the solder masks.
